(19) United States
(12) Patent Application Publication
(10) Pub. No.: US 2006/0046465 A1
(43) Pub. Date: Mar. 2, 2006

(54) Method for manufacturing a semiconductor device

(75) Inventor: Joon-Bum Shim, Seongnam-city (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/213,395

(22) Filed: Aug. 25, 2005

(30) Foreign Application Priority Data
Aug. 27, 2004 (KR) 10-2004-0067995
Sep. 17, 2004 (KR) 10-2004-0074506

(51) Int. Cl. H01L 21/4763; H01L 21/302

(52) U.S. Cl. 438/622; 438/723

(57) ABSTRACT

An increase in parasitic capacitance between lines, an increase of contact resistance, and corrosion of a metal line may be effectively reduced or prevented when a semiconductor device is manufactured by a method including forming an interlayer insulating layer including a low-k dielectric material on a semiconductor substrate having a structure thereon, etching the interlayer insulating layer to form a hole and expose a portion of the structure, and cleaning the hole using an inorganic cleaning agent.

### CROSS-REFERENCE TO RELATED APPLICATION

This application claims priority to and the benefits of Korean Patent Application No. 10-2004-0067995 filed in the Korean Intellectual Property Office on Aug. 27, 2004, and Korean Patent Application No. 10-2004-0074506 filed in the Korean Intellectual Property Office on Sep. 17, 2004, the entire contents of which are incorporated herein by reference.

### BACKGROUND OF THE INVENTION

(a) Field of the Invention

The present invention relates to a method for manufacturing a semiconductor device. More particularly, the present invention relates to a method for manufacturing a semiconductor device having an interlayer insulating layer comprising a low-k dielectric material.

(b) Description of the Related Art

Generally, wiring technology refers to a technology for realizing interconnections, power supplying routes, and signal transmission routes in an integrated circuit (IC).

Recently, as semiconductor devices have been highly integrated and process technology has been enhanced, conventional aluminum lines have been replaced by copper lines for improving device characteristics such as operation speed and resistance of the device, as well as parasitic capacitance between metal lines. Typically, such copper lines are formed by a damascene process.

The copper line may be narrower in line width than a conventional aluminum line, and an RC delay may be caused due to an increase in parasitic capacitance between lines.

In order to solve such a problem, for a semiconductor device having copper lines, an interlayer insulating layer may be formed from a low-k (low dielectric constant) dielectric material (e.g., a material having a dielectric constant k of about 2 to 3), such as silicon oxycarbide (SiOC), instead of the typical silicon oxide.

According to the damascene process for forming a copper line, a damascene structure including a via hole and a trench is formed in the interlayer insulating layer by a photolithography and etching process. Then, after filling a copper layer in the damascene structure, an overflowing portion of the copper layer is removed by an etch back process or chemical mechanical polishing (CMP).

Some low-k insulating layers, such as a SiOC layer, may show carbon-based polymer characteristics. When such a low-k insulating layer is used as an interlayer insulating layer, a substantial amount of carbon-based polymers are produced while etching the interlayer insulating layer to form the damascene structure, and they remain at the bottom and lateral sides of the damascene structure after the etching.

Conventionally, in order to remove such carbon-based polymers, a cleaning process is performed using an organic solvent after forming the damascene structure. However, since conventional organic solvents tend to be somewhat viscous, the organic solvent may remain in the interlayer insulating layer after the cleaning process. In this case, the dielectric constant k value of the interlayer insulating layer is increased, thereby also increasing parasitic capacitance between lines.

In addition, since the organic solvent or polymers may remain in the damascene structure, corrosion of the copper line and an increase of contact resistance may be caused, and operation speed and reliability of the semiconductor device may deteriorate.

The above information disclosed in this Background section is only for enhancement of understanding of the background of the invention and therefore it may contain information that does not form prior art that is already known in this or any other country to a person of ordinary skill in the art.

### SUMMARY OF THE INVENTION

The present invention has been made in an effort to provide a method for manufacturing a semiconductor device having an advantage of improved reliability by fully removing polymers produced while etching a low-k insulating layer.

An exemplary method of manufacturing a semiconductor device according to an embodiment of the present invention includes forming an interlayer insulating layer of a low-k dielectric material on a semiconductor substrate having a structure thereon, forming a hole in the interlayer insulating layer by etching the interlayer insulating layer such that the structure is partially exposed therethrough, and cleaning the hole using an inorganic cleaning agent.

In one embodiment, hydrogen fluoride (HF) vapor may be used for cleaning the hole for a metal line.

The interlayer insulating layer may further include an etch stop layer, preferably under the low-k dielectric material.

In this case, forming the hole may include forming a via hole exposing the etch stop layer by etching the interlayer insulating layer (e.g., the low-k dielectric material), forming a trench overlapping the via hole by partially removing the interlayer insulating layer (e.g., at least the low-k dielectric material), and removing the etch stop layer exposed through the via hole.

The HF vapor may be formed by flowing nitrogen (N₂) gas through a HF solution. The HF solution may have a HF concentration of about 39.5% by weight.

The nitrogen gas may have a temperature of about 180° C., the HF vapor may have a temperature of 40-90° C., and/or the substrate may have a temperature of 70-80° C.

An exemplary method for manufacturing a semiconductor device according to an exemplary embodiment of the present invention may further include filling an upper metal line in the hole. In this case, the structure on or in the semiconductor substrate may include a lower metal line, and the upper metal line may connect with the lower metal line through the hole.

The lower metal line and upper metal line may comprise copper lines.

The device may include a damascene structure including a via hole (e.g., the hole in the interlayer insulating layer) and a trench.

The low-k dielectric material may include a silicon oxycarbide-(SiOC) based material.

During the cleaning of the hole for a metal line, the substrate having the hole therein may be cleaned with a solution of deionized water and a 49% by weight HF (HF) solution. The HF solution and the deionized water may be mixed at a ratio of 0.1-10 parts by weight of the HF solution and 600-1200 parts by weight of deionized water.

A single wafer cleaner may be employed in the cleaning step.

In the cleaning, a cleaning temperature may be from 30 to 60° C. The cleaning step may further comprise rotating the substrate at a rotation speed of from 500 to 1000 rpm, and/or injecting the cleaning solution at a flow rate of 1 to 1.5 liters per minute (lpm).

### BRIEF DESCRIPTION OF THE DRAWINGS

FIG. 1A to FIG. 1E are cross-sectional views showing sequential stages of a method for manufacturing a semiconductor device according to a first exemplary embodiment of the present invention, wherein FIG. 1E is a cross-sectional view of a semiconductor device according to the first exemplary embodiment of the present invention.

FIG. 2A to FIG. 2C are cross-sectional views showing sequential stages of a method for manufacturing a semiconductor device according to a second exemplary embodiment of the present invention, wherein FIG. 2C is a cross-sectional view of a semiconductor device according to the second exemplary embodiment of the present invention.

### DETAILED DESCRIPTION OF THE EMBODIMENTS

With reference to the accompanying drawings, the present invention will be described in order for those skilled in the art to be able to implement the invention. As those skilled in the art would realize, the described embodiments may be modified in various different ways, all without departing from the spirit or scope of the present invention.

To clarify multiple layers and regions, the thicknesses of the layers are enlarged in the drawings. Like reference numerals designate like elements throughout the specification.

When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

Firstly, a semiconductor device according to a first exemplary embodiment of the present invention will hereinafter be described in detail with reference to the accompanying drawings.

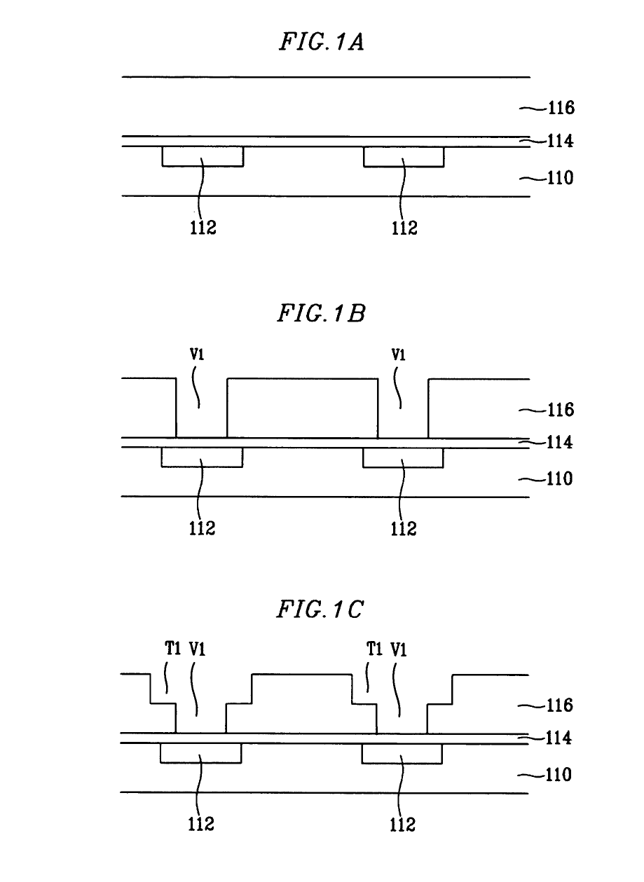

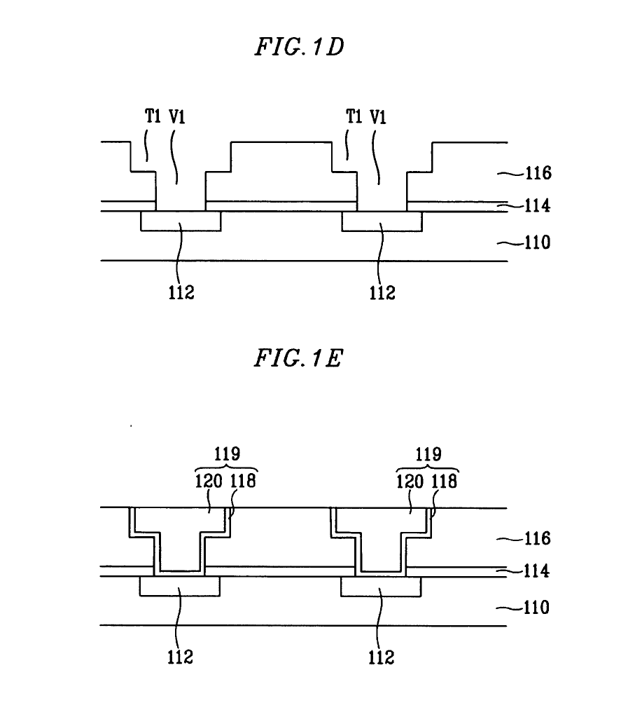

FIG. 1A to FIG. 1E are cross-sectional views showing sequential stages of a method for manufacturing a semiconductor device according to a first exemplary embodiment of the present invention, wherein FIG. 1E is a cross-sectional view of a semiconductor device according to the first exemplary embodiment of the present invention.

As shown in FIG. 1E, an etch stop layer 114 and an interlayer insulating layer 116 are formed on a semiconductor substrate 110 having a lower structure thereon, such as a lower metal line 112 (e.g., a copper line). The etch stop layer 114 may comprise silicon nitride, etc., and the interlayer insulating layer 116 may comprise a low-k dielectric material (e.g., a SiOC-based material) having a dielectric constant lower than about 4 (more precisely, lower than the dielectric constant of SiO₂).

A metal line 119 filling a via hole V1 and a trench T1 (see FIG. 1D) is formed through the etch stop layer 114 and the interlayer insulating layer 116, such that upper and lower wiring and/or circuits may be interconnected thereby. Referring back to FIG. 1E, the upper metal line 119 includes (1) a diffusion barrier 118 formed on an interior surface of the via hole V1 and the trench T1 and (2) a bulk metal layer 120 filling the via hole V1 and the trench T1, and defined in part by the diffusion barrier 118. Here, the diffusion barrier 118 may comprise a titanium nitride (TiN), tantalum nitride (TaN), or tantalum silicon nitride (TaSiN) layer. In addition, the bulk metal layer 120 generally comprises a conductive material such as copper (Cu) that has low resistance.

Hereinafter, a method for manufacturing the semiconductor device shown in FIG. 1 according to an exemplary embodiment of the present invention will be described in detail with reference to FIG. 1A to FIG. 1E

Firstly, as shown in FIG. 1A, the etch stop layer 114 is formed on the semiconductor substrate 110 having the lower structure thereon, such as the metal lines 112 insulated from each other. The etch stop layer 114 is formed by depositing silicon nitride SiN on the semiconductor substrate 110, e.g., to a thickness of 300-600 Å. Then the interlayer insulating layer 116 is formed on the etch stop layer 114 by depositing a low-k dielectric material, such as a SiOC-based material. Alternatively, the low-k dielectric material may comprise a fluorinated silica glass (FSG), which may further comprise an undoped silica glass (USG) layer on either or both of the upper and lower surfaces of the FSG layer.

Then, referring to FIG. 1B, a photosensitive layer pattern (not shown) is formed on the interlayer insulating layer 116 to define the via hole V1. Then, the via hole V1 is formed by dry and/or plasma etching the low-k dielectric material 116 using the photosensitive layer pattern as a mask until the etch stop layer 114 is exposed.

Now, referring to FIG. 1C, the photosensitive layer pattern is removed with an oxygen plasma, and a new photosensitive layer pattern (not shown) is formed to define a trench T1. Then, the trench T1 overlapping the via hole V1 is formed by dry etching the interlayer insulating layer 116 (e.g., the low-k dielectric material) using the new photosensitive layer pattern as a mask.

Subsequently, referring to FIG. 1D, the portion of the etch stop layer 114 exposed by the via hole V1 is removed (generally, by dry and/or plasma etching) such that the lower metal line 112 may be exposed.

Subsequently, the via hole V1 and the trench T1 are cleaned such that polymers and/or other carbon-based and/or carbon-containing materials produced during the etching may be removed. In this case, hydrogen fluoride (HF) vapor is used in the cleaning of the via hole V1. Thus, the cleaning agent may comprise HF (e.g., HF vapor). The HF vapor may be formed by flowing nitrogen (N₂) gas into a container containing a HF solution having a HF concentration of 39.5% by weight. Although nearly any concentration of HF can be suitable, relatively concentrated solutions are preferred (e.g., from about 35 wt. % to about 48 wt. %). Generally, the nitrogen gas is passed through the HF solution to maximize the concentration of HF vapor in the carrier (nitrogen) gas. The nitrogen gas flowed into the container may have a temperature of from about 100° C. to about 250° C. (e.g., about 180° C.), and the HF vapor produced thereby may have a temperature of 40-90° C. In addition, a temperature of the substrate 110 may be maintained at 70-80° C. to enhance the reactivity and/or cleaning action of the HF vapor with polymers or other carbon-containing material on the substrate (e.g., in the via hole or trench).

When HF vapor is used in the cleaning process after etching the via hole V1 and/or the trench T1, polymers or other carbon-containing material may be fully removed, without causing a change in a critical dimension (CD) of the via hole and/or the trench and without causing an increase in the dielectric constant of the insulating layer.

Subsequently, as shown in FIG. 1E, a first metal or conductive layer (i.e., the diffusion barrier 118) is thinly deposited on an interior surface of the via hole V1 and the trench T1 by depositing thereon a metal such as titanium, tantalum and/or an alloy or conductive compound thereof (e.g., TiN, TaN, TaSiN, etc.). Then, a second metal layer (i.e., the bulk metal layer 120) is deposited into the via hole V1 and the trench T1 (e.g., by conventional electroplating and/or CVD), which may be defined in part by the first metal layer 118. Copper, which is a metal showing low resistance, is used as the second metal layer 120.

Subsequently, a chemical mechanical polishing process is performed to expose an upper surface of the interlayer insulating layer 116, such that the metal line 119 fills the via hole V1 and the trench T1 substantially exactly.

As described above, according to an exemplary embodiment of the present invention, HF gas is used in the cleaning process after etching a low-k insulating layer, and thus, polymers and/or carbon-containing contaminants produced from etching the low-k insulating layer may be fully removed without causing deterioration of performance of a semiconductor device. Therefore, a higher quality semiconductor device using a low-k dielectric insulating layer may be achieved.

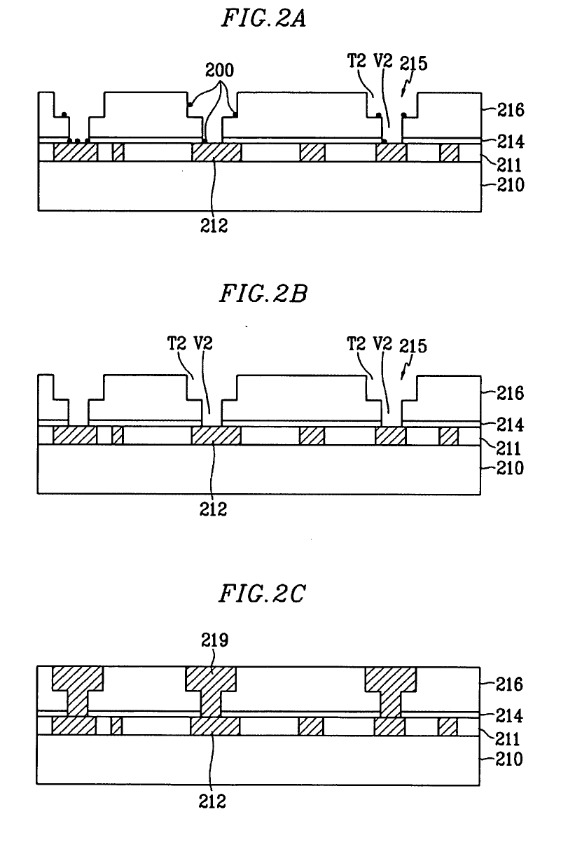

Hereinafter, a method for manufacturing a semiconductor device according to a second exemplary embodiment of the present invention will be described in detail with reference to FIG. 2A to FIG. 2C.

Referring to FIG. 2A, a semiconductor substrate 210 is prepared. The semiconductor substrate 210 includes, at an upper portion thereof, a structure such as lower copper lines 212 and an insulating layer 211 insulating between the lower copper lines 212.

Then, an etch stop layer 214 is formed over the substrate 210 so as to prevent diffusion of the copper, and an interlayer insulating layer 216 is formed on the etch stop layer 214. Here, the etch stop layer 214 may comprise a silicon carbide (SiC) layer having a thickness of from 100 to 400 Å, and the interlayer insulating layer 216 may comprise a low-k insulating layer such as a SiOC layer.

Subsequently, a via hole V2 is formed by etching the interlayer insulating layer 216 such that a portion of the etch stop layer 214 on the lower copper line 212 may be exposed therethrough. Now, a trench T2 is formed by etching the interlayer insulating layer 216 above the via hole V2, such that a damascene structure 215 including the via hole V2 and the trench T2 is formed. Then, the etch stop layer 214 at a bottom of the damascene structure 215 is etched to expose the lower copper line 212. At this time, a substantial amount of carbon-based polymers (or contaminants) 200 may remain at the bottom and lateral sides of the damascene structure 215, as shown in the drawing.

According to the present exemplary embodiment, the via hole V2 is formed prior to the trench T2 during the formation of the damascene structure 215. However, the present invention is not limited thereto, and encompasses the reversed process (i.e., where the trench T2 may be formed prior to the via hole V2).

Referring to FIG. 2B, the polymers 200 in the damascene structure 215 are substantially or fully removed by performing a cleaning process (e.g., in a conventional single wafer cleaner) using a mixed solution of deionized water and a 49% HF solution as the cleaning solution or cleaning agent. Here, the HF solution and the deionized water are mixed in a mixture ratio of 0.1-10 wt. % (or parts by weight) of HF solution and 600-1200 wt. % (or parts by weight) of deionized water.

In more detail, during the cleaning process, the substrate having the polymers 200 thereon is held by a wafer chuck of the single wafer cleaner, and the above-described cleaning solution is injected therein through a nozzle while rotating the substrate by a motor (which may drive rotational motion of the chuck). At this time, a cleaning temperature may be controlled to 30 to 60° C., a rotational speed of the substrate may be controlled to 500 to 1000 rpm, and a flow rate of the injected cleaning solution may be controlled to 1 to 1.5 lpm.

Since an inorganic chemical solution (such as aqueous HF) has a relatively small or negligible viscosity in comparison with an organic solvent, the inorganic chemical solution generally does not remain in the interlayer insulating layer 216 after the cleaning process. Consequently, the dielectric constant k of the interlayer insulating layer 216 is generally not changed, and the damascene structure 215 becomes free from the cleaning solution after the cleaning process.

In addition, since a single wafer cleaner may be employed, the substrate is not necessarily transferred from bath to bath, and therefore contamination and/or foreign materials that may remain in a multi-wafer cleaning bath may be kept from contaminating the substrate.

Subsequently, referring to FIG. 2C, a copper layer is deposited on the interlayer insulating layer 216 to fill the damascene structure 215 by an electroplating method, and the copper layer is processed by CMP or etch back such that the interlayer insulating layer 216 may be exposed. Thereby, an upper copper line 219 contacting the lower copper line 212 is completed.

As described above, according to an exemplary embodiment of the present invention, an interlayer insulating layer comprising a low-k dielectric material may be cleaned by a cleaning process using an inorganic chemical agent or solution, after forming a damascene structure in the interlayer insulating layer. Therefore, the dielectric constant k of the interlayer insulating layer generally does not change, and the damascene structure may become relatively free from remaining or residual cleaning solution. Accordingly, an increase of parasitic capacitance between lines, corrosion of a copper line, an increase of contact resistance, etc., may be effectively reduced, minimized or prevented, and thereby reliability of metal lines may be improved.

In addition, throughput may also be improved since contamination of and/or foreign materials on the substrate may be reduced or prevented during the cleaning process by employing a single wafer cleaner.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a semiconductor device, comprising:
forming an interlayer insulating layer comprising a low-k dielectric material on a semiconductor substrate having a structure thereon;
forming a hole in the interlayer insulating layer by etching the interlayer insulating layer such that the structure is partially exposed therethrough; and
cleaning the hole with an inorganic cleaning agent.

2. The method of claim 1, wherein the inorganic cleaning agent comprises hydrogen fluoride (HF) vapor.

3. The method of claim 2, wherein the interlayer insulating layer further comprises an etch stop layer under the low-k dielectric material, and forming the hole comprises:
forming a via hole exposing the etch stop layer by etching the low-k dielectric material;
partially removing the interlayer insulating layer to form a trench overlapping with at least part of the via hole; and
removing the etch stop layer exposed through the via hole.

4. The method of claim 2, further comprising forming the HF vapor by flowing nitrogen (N₂) gas through a HF solution in a container.

5. The method of claim 4, wherein the HF solution has a concentration of from about 35% by weight to about 48% by weight.

6. The method of claim 4, wherein the HF solution has a concentration of about 39.5% by weight.

7. The method of claim 4, wherein the nitrogen gas has a temperature of from about 100° C. to about 250° C.

8. The method of claim 4, wherein the nitrogen gas has a temperature of about 180° C.

9. The method of claim 2, wherein the HF vapor has a temperature of 40-90° C.

10. The method of claim 2, wherein the substrate has a temperature of 70-80° C.

11. The method of claim 1, further comprising filling an upper metal line in the hole, wherein:
the structure comprises a lower metal line; and
the upper metal line connects with the lower metal line through the hole.

12. The method of claim 11, wherein the lower metal line and upper metal line comprise copper.

13. The method of claim 1, comprising a damascene structure including the hole and a trench.

14. The method of claim 1, wherein the low-k dielectric material includes a silicon oxycarbide-(SiOC) based material.

15. The method of claim 1, wherein cleaning the hole, comprises cleaning the substrate having the hole with a solution comprising deionized water and a 49% HF solution.

16. The method of claim 15, wherein the HF solution and the deionized water are present in a ratio of 0.1-10 parts by weight of the HF solution and 600-1200 parts by weight of the deionized water.

17. The method of claim 15, wherein the cleaning step is performed in a single wafer cleaner.

18. The method of claim 15, wherein the cleaning is conducted at a temperature of from 30 to 60° C.

19. The method of claim 15, wherein the cleaning further comprises rotating the substrate at a rotation speed of from 500 to 1000 rpm, and injecting the cleaning solution at a flow rate of from 1 to 1.5 liters per minute.
